(19) United States
(12) Patent Application Publication
(10) Pub. No.: US 2006/0102922 A1
(43) Pub. Date: May 18, 2006

(54) LED heat dissipation support

(75) Inventors: Ching-Yi Wu, Hsinchu Hsien (TW); Cheng Tsung Lin, Ping Cheng City (TW); I-Hung Chan, Ping Cheng City (TW); Ray-Hua Horng, Taichung City (TW)

Correspondence Address: TROXELL LAW OFFICE PLLC, SUITE 1404, 5205 LEESBURG PIKE, FALLS CHURCH, VA, 22041, US

(73) Assignee: Kenly Precision Industrial Co., Ltd.

(21) Appl. No.: 10/986,856

(22) Filed: Nov. 15, 2004

(51) Int. Cl. H01L 29/22

(52) U.S. Cl. 257/100

(57) ABSTRACT

A light emitting diode chip carrier to improve heat dissipation by providing a thicker heat dissipation area between two supports that carry the light-emitting chip; and heat absorption and dissipation results by the metallic material help absorb the heat generated by the acting light emitting chip for the LED to maintain normal working temperature without being over-heated and damaged.

### BACKGROUND OF THE INVENTION

(a) Field of the Invention

The present invention is related to a light emitting diode support in the chip carrier to improve heat dissipation.

(b) Description of the Prior Art

The light emitting diode is related to a light emitting device (LED) that emits spectrum of different frequencies is comprised of a semiconductor to emit photons by integrating electrons and holes in the crystal of semi-conductor. That is, an LED chip is comprised of an n-semiconductor crystal and a p-semiconductor crystal. Where both semiconductor crystals are conducted, excessive electrons from the n-semiconductor crystal flows into the holes of the p-semiconductor. The difference in potentials causes the release of energy in the process of those electrons from the n-semiconductor crystal flowing into the p-semiconductor crystal, and the energy is released in the form of light to generate light beams in different wavelength.

Referring to FIG. 1 of the accompanying drawings for a basic configuration of an LED generally available in the market. Wherein, the LED is provided with two supports 10; the light-emitting chip 20 is insulated and fixed to either support 10, a gold plated wire 30 (or a conductor of the similar conduction function) provides electric conduction among both supports 10 and an electrode layer 21 of the light-emitting chip 20 so to apply different voltages between both supports to create positive and negative electrodes respectively for both supports 10; and to release energy to emit light when electrons and holes are integrated.

However, the heat generated in the course of the operation of the light-emitting chip 20 of the LED fails to be effectively dissipated to gradually raise the temperature of the entire LED to such extent that fails the LED.

### SUMMARY OF THE INVENTION

The primary purpose of the present invention is to provide an improved construction of the heat dissipation support in an LED. To achieve the purpose, both metallic supports are given with different polarities. Wherein, a thicker heat dissipation area formed at where the support carries the light-emitting chip absorbs the heat generated in the operation of the light-emitting chip.

Heat absorption and dissipation results provided by the metallic material help the LED maintain normal working temperature without being overheated and damaged.

### BRIEF DESCRIPTION OF THE DRAWINGS

FIG. 1 is a schematic view showing a support construction of an LED of the prior art.

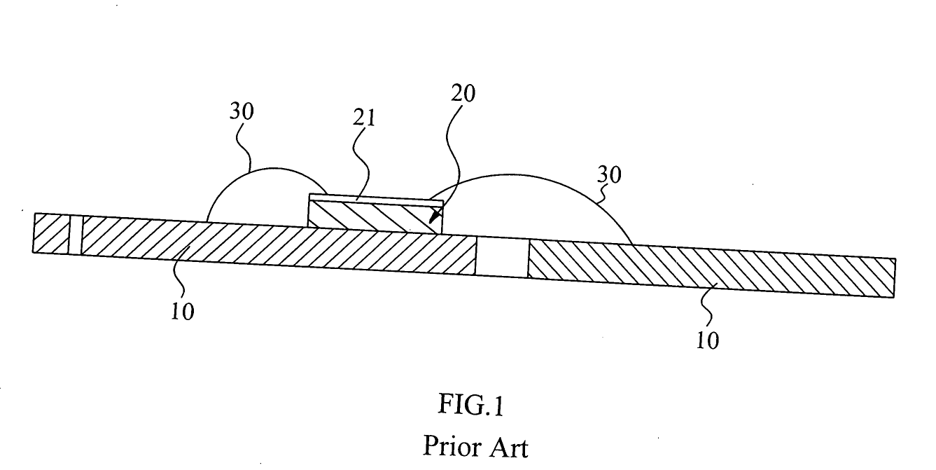

FIG. 2 is a schematic view showing a support construction of an LED of the present invention.

FIG. 3 is a side view of a support construction of the LED of the present invention.

FIG. 4 is a schematic view showing both supports and a case of the LED of the present invention.

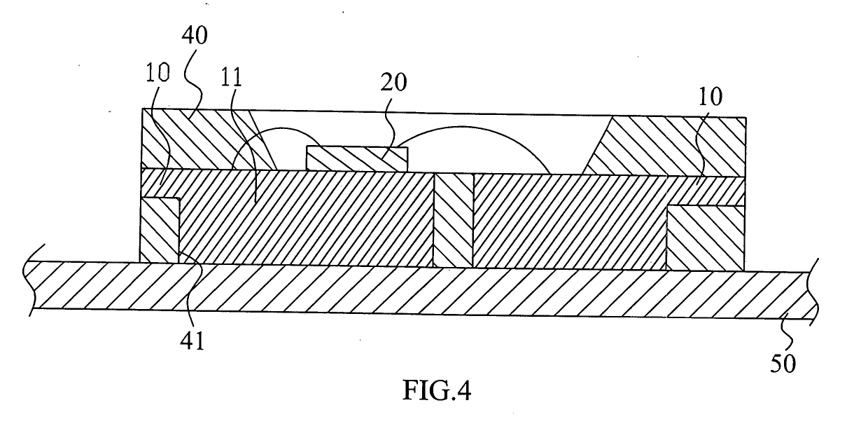

FIG. 5 is a schematic view showing another type of arrangement of both supports and the case of the LED of the present invention.

### DETAILED DESCRIPTION OF THE PREFERRED EMBODIMENTS

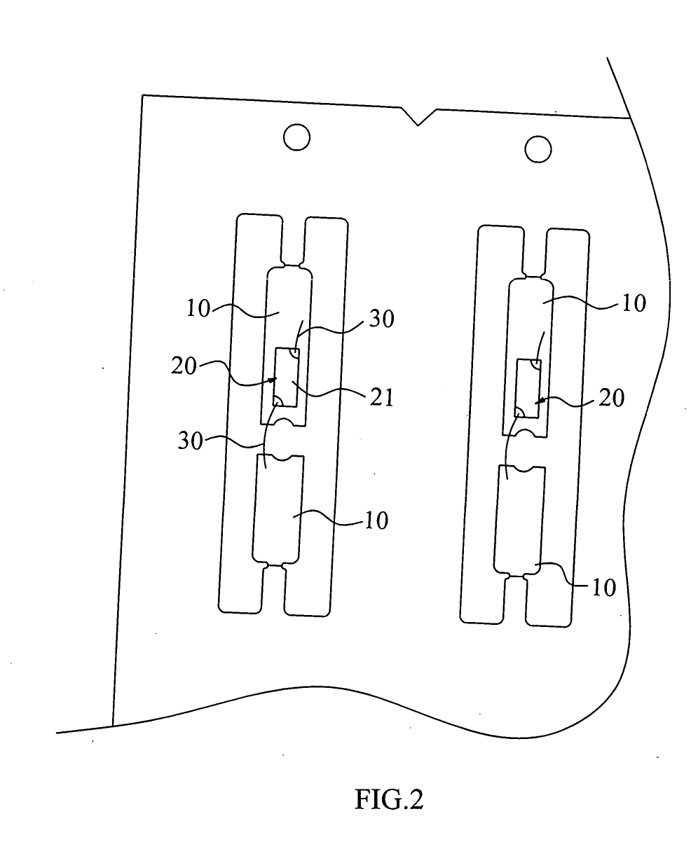

Referring to FIG. 2 for a basic configuration of an LED of the present invention, two metallic supports 10 given with different electrodes from each other and a light-emitting chip 20 is insulated and fixed to either support 10; and a golden plated wire 30 or a conductor of the similar conductive function connects an electrode 21 of the light-emitting chip 20 to both supports 10. Accordingly, when voltage is applied to where between both supports 10, energy is released as a result of the integrated electronics and holes to emit the light.

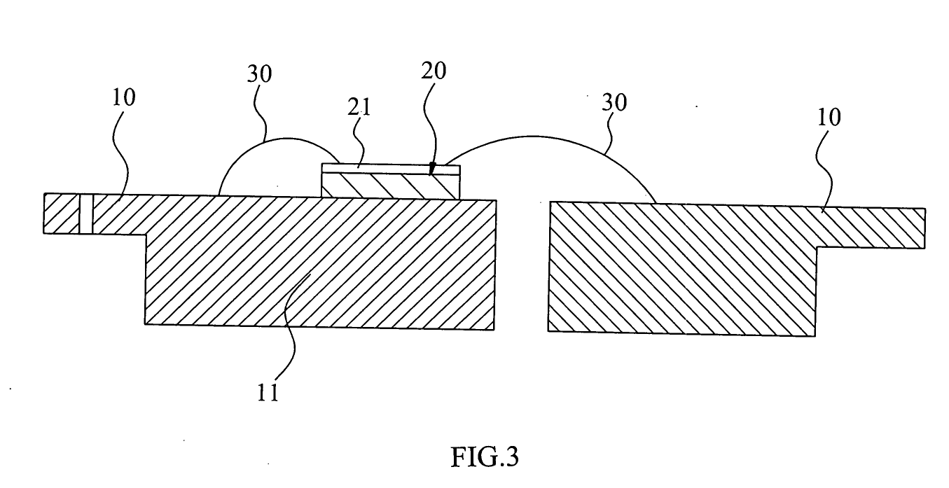

A thicker heat dissipation area 11 is provided at where the support 10 carries the light-emitting chip 20 as illustrated in FIG. 3. The light-emitting chip 20 is insulated and fixed to the heat dissipation area 11, and the golden plated wire 30 or a conductor of the similar conductive function connects the electrode layer 21 of the light-emitting chip 20 to both supports 10. The heat dissipation area 11 absorbs the heat generated by the acting light-emitting chip 20. The heat absorption and dissipation results provided by the metallic material help maintain the LED in normal working temperature thus to protect the LED from being overheated and damaged.

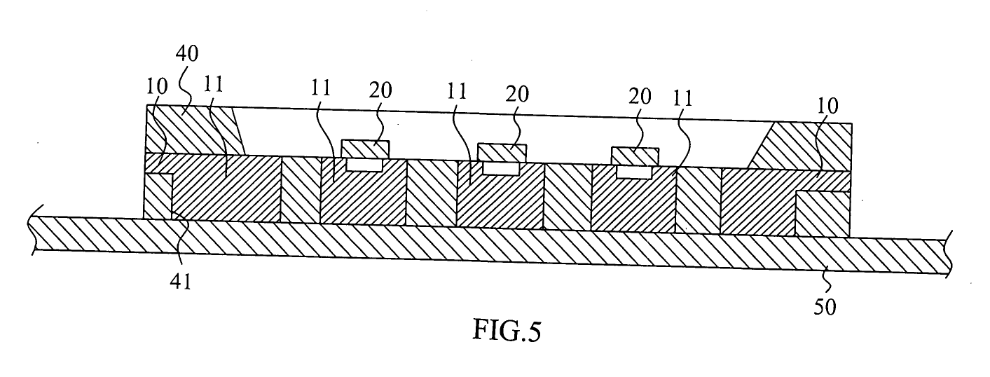

The LED is fixed into a case 40 as illustrated in FIG. 5. The case 40 is made of plastic material including but not limited to polyphthalamide (PPA). A window 41 is each formed on the bottom of the case at where respectively in relation to both supports 10 so to expose both supports 10 and to secure both supports to a circuit board 50. The case 40 facilitates the fixation of the LED to a proper position in a LCD for utilizing light source created by the operation of the light-emitting chip 20 for the LCD to display while promoting the luminance due to different deflection to the light source by the material of the case 40.

Furthermore, multiple heat dissipation areas 11 are provided to the case 40 for the installation of multiple chips 20 of different colors as illustrated in FIG. 5 so to emit the light in color as desired by mixing colors of those light-emitting chip 20 in different colors.

The present invention provides an improved structure of an LED supports to better dissipate the heat for protection of the LED from being overheated; and this application for a utility patent is duly filed accordingly. However, it is to be noted that the preferred embodiments disclosed in the specification and the accompanying drawings are not limiting the present invention; and that any construction, installation, or characteristics that is same or similar to that of the present invention should fall within the scope of the purposes and claims of the present invention.

1. An LED heat dissipation support construction is comprised of two metal supports of polarities different from each other; a thick heat dissipation area being formed on either support at where carries a light emitting chip; heat generated from the acting light emitting chip being absorbed and dissipated by the metallic material of the heat dissipation area to help maintain the LED at a normal working temperature.

2. An LED heat dissipation support construction is comprised of having a light-emitting chip provided on two metallic supports in different polarities from each other; a light source created by the light-emitting chip providing an LCD the function to display; a thick heat dissipation area being formed on the support at where the support carries the light-emitting chip; the LED being fixed in a box; and the box being permitted to be further fixed to a proper position in the LCD.

3. The LED heat dissipation support construction of claim 2;
wherein, the case is made of plastic material including but not limited to polyphthalamide (PPA).

4. The LED heat dissipation support construction of claim 2;
wherein, two windows are provided on the bottom of the case at where in relation to the locations of both supports to expose both supports.
